(19) United States
(12) Patent Application Publication
(10) Pub. No.: US 2013/0161800 A1
(43) Pub. Date: Jun. 27, 2013

(54) PCB FOR MUF AND MOLDING STRUCTURE OF THE PCB

(71) Applicant: SAMSUNG ELECTRONICS CO., LTD., Suwon-Si (KR)

(72) Inventors: Hak-kyoon BYUN, Hwaseong-si (KR); Tae-hun KIM, Cheonan-si (KR); Ji-hyun PARK, Suwon-si (KR); Byung-cheol JEON, Cheonan-si (KR); Seung-jin CHEON, Asan-si (KR)

(73) Assignee: SAMSUNG ELECTRONICS CO., LTD., Suwon-Si (KR)

(21) Appl. No.: 13/674,328

(22) Filed: Nov. 12, 2012

(30) Foreign Application Priority Data
Dec. 21, 2011 (KR) 10-2011-0139216

(51) Int. Cl. H01L 23/18

(52) U.S. Cl. CPC H01L 23/18
USPC 257/667; 257/E23.136

(57) ABSTRACT

A printed circuit board (PCB) for molded underfill (MUF) and a PCB molding structure that may expand a range of applying the PCB and may resolve a problem of generation of a void during manufacturing of a semiconductor package. The PCB includes: a molding area on which a plurality of semiconductor chips are mounted and that is sealed; and a peripheral area that is formed around the molding area, contacts a mold for molding during a molding process, and includes a first side adjacent to a portion into which a molding material is injected and a second side that faces the first side that is adjacent to a portion from which air may be discharged, wherein an active area where the semiconductor chips are disposed in the molding area is disposed nearer the first side than to the second side.

### CROSS-REFERENCE TO RELATED APPLICATIONS

This application claims the benefit of Korean Patent Application No. 10-2011-0139216, filed on Dec. 21, 2011, in the Korean Intellectual Property Office, the disclosure of which is incorporated herein in its entirety by reference.

### BACKGROUND

The inventive concepts relate to a semiconductor package, and more particularly, to a printed circuit board (PCB) for manufacturing a semiconductor package and a molding structure of the PCB in which chips are sealed on the PCB through a molded underfill (MUF) process.

In general, chip-on-board (COB) type semiconductor packages are manufactured by mounting a semiconductor chip on a PCB, electrically connecting a circuit pattern formed in the PCB and the semiconductor chip to each other, and then molding the semiconductor chip, which has been recently used in integrated chip (IC) cards, and the like. In this regard, the PCB is manufactured as a strip structure in which a plurality of PCBs are formed to improve a process throughput during manufacturing of the PCB or manufacturing of the semiconductor package by using the PCB.

Recently, such a PCB has been mainly used in a ball grid array package, a pin grid array package, a chip size package, and the like because the PCB has high density and high reliability of a circuit pattern satisfying needs of a semiconductor chip having a high-density input-output pin such as an IC, an LSI, or the like.

### SUMMARY

One embodiment of the inventive concepts provides a printed circuit board (PCB) for molded underfill (MUF) and a molding structure of the PCB that may expand a range of applying the PCB and may resolve a problem of generation of a void during manufacturing of a semiconductor package as described herein.

Another embodiment of the inventive concepts also provides a PCB for MUF and a molding structure of the PCB that may smoothly perform a molding process and reduce generation of a void by resolving a problem of leakage of a sealing material.

According to an embodiment of the inventive concepts, there is provided a printed circuit board (PCB) for molded underfill (MUF), the PCB including a molding area on which a plurality of semiconductor chips are mounted and that is sealed; and a peripheral area around a periphery of the molding area, the peripheral area being configured to contact a mold during a molding process, and includes a first side adjacent to an injection portion of the molding area into which a molding material is injected and a second side parallel to the first side and is adjacent to a vent portion configured to discharge air, and an active area within the molded area where the semiconductor chips are disposed in the molding area is located closer to the first side than the second side of the peripheral area.

The active area may include a plurality of semiconductor package footprints, each including a semiconductor chip. A distance between an edge of the active area and an edge of the molding area in nearest the second side may be equal to or less than a width of one semiconductor package footprint.

The PCB for MUF may have a rectangular strip structure, and guide holes may be located only in four vertices of the PCB for MUF. A guide hole may not be formed in a center portion of the second side of the peripheral area, and a thickness of the PCB for MUF of the second side may be uniform.

The molding area may be designed as one body and a block distinguishing area is not formed in the PCB for MUF.

According to another embodiment according to the inventive concepts, there is provided a printed circuit board (PCB) for molded underfill (MUF), the PCB may include: a molding area on which a plurality of semiconductor chips are mounted and that is sealed; and a peripheral area formed around the molding area, contacts a mold during a molding process, and includes a first side adjacent to an injection portion of the molding are into which a molding material is injected during a molding process and a second side that faces the first side and is adjacent to a portion from which air is discharged, wherein a thickness of the second side is uniform.

The PCB for MUF may have a rectangular strip structure, guide holes may be formed only in four vertices of the PCB for MUF, and no guide hole may be formed in a center portion of the second side.

According to another aspect of the inventive concepts, there is provided a printed circuit board (PCB) for MUF; the semiconductor chips mounted on an active area of the PCB for MUF; and a sealing material on the molding area and sealing the semiconductor chips.

The PCB for MUF may have an active area may include a plurality of semiconductor package footprints, each including a semiconductor chip. The PCB for MUF may have a distance between an edge of the active area and an edge of the molding area nearest the second side is equal to or less than a width of one semiconductor package footprint.

The PCB for MUF may have a rectangular strip structure, guide holes only in four vertices of the PCB for MUF, no guide hole in a center portion of the second side, and a uniform thickness of the PCB for MUF of the second side.

The PCB for MUF may have a sealing material forms as one body.

Top surfaces of the semiconductor chips may be exposed through the sealing material. Each of the semiconductor chips may be mounted on the PCB for MUF through a plurality of bumps, and the sealing material may be filled in a space between the semiconductor chips and the PCB for MUF.

A reservoir pattern may be formed on the second side of the peripheral area.

Two or more semiconductor chips may be stacked on the active area.

According to another aspect of the inventive concepts, there is provided a printed circuit board (PCB) for molded underfill (MUF), the PCB may include an injection side configured to accept sealing material during a molding process, a vent side configured to discharge air during the molding process and an active area configured to receive semiconductor chips thereon, the active area located closer to the injection side than to the vent side of the PCB and the active area configured to be sealed during the molding process.

The PCB may have semiconductor chips on the active area.

The top surfaces of the semiconductor chips may be covered with sealing material during a molding process.

The PCB may include a plurality of stacked semiconductor chips.

The PCB may include a reservoir portion adjacent to the vent portion.

### BRIEF DESCRIPTION OF THE DRAWINGS

Example embodiments of the inventive concepts will be more clearly understood from the following detailed description taken in conjunction with the accompanying drawings in which:

FIGS. 1 through 7 are plan views of a printed circuit board (PCB) for molded underfill (MUF), according to embodiments of the inventive concepts;

FIG. 8 is a plan view of a PCB molding structure of the PCB for MUF of FIG. 1, according to an embodiment of the inventive concepts;

FIG. 9 is a plan view of a PCB molding structure of the PCB for MUF of FIG. 1, according to another embodiment of the inventive concepts;

FIG. 10 is a plan view of a PCB molding structure of the PCB for MUF of FIG. 1, according to another embodiment of the inventive concepts;

FIG. 11 is a cross-sectional view of a PCB molding structure of the PCB for MUF of FIG. 8 taken along a line

FIG. 12 is a cross-sectional view of a PCB molding structure of the PCB for MUF of FIG. 9 taken along a line II-II ;

FIG. 13 is a cross-sectional view of a PCB molding structure of the PCB for MUF of FIG. 10 taken along a line I-I′; and

FIG. 14 is a cross-sectional view of a PCB molding structure of the PCB for MUF of FIG. 8 taken along a line I-I′ according to another embodiment of the inventive concepts.

### DETAILED DESCRIPTION OF THE EMBODIMENTS

Example embodiments will now be described more fully with reference to the accompanying drawings. Example embodiments may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements throughout, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments. It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless othenvise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

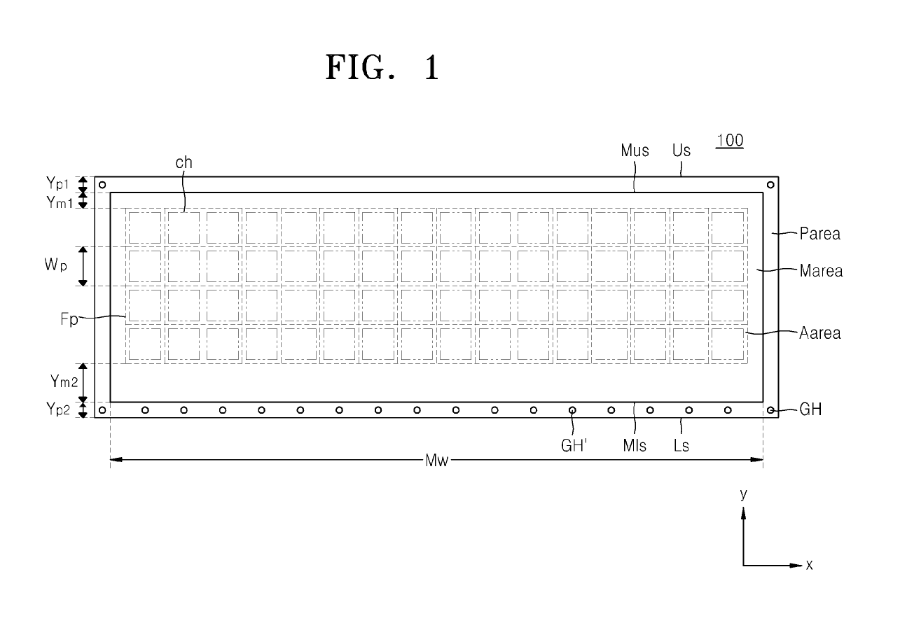

FIGS. 1 through 7 are plan views of printed circuit boards (PCBs) 100 to 100f for molded underfill (MUF), according to embodiments of the inventive concepts.

Referring to FIG. 1, a PCB for MUF may be roughly divided into a molding area Marea and a peripheral area Parea. The PCB 100 for MUF may have a strip structure extending in a horizontal direction (x direction).

The molding area Marea is an area where a plurality of semiconductor chips are mounted and sealed with a sealing material. The molding area Marea may include an active area Aarea where the semiconductor chips are mounted. In this regard, the active area Aarea is represented by a rectangular portion surrounded by a dashed line in the molding area Marea.

The active area Aarea may include a plurality of chip mounting portions //ch on which the plurality of semiconductor chips are mounted, respectively. The chip mounting portions ch are illustrated as two-dash chain lines. A dash-lined small quadrangle surrounding each chip mounting portion ch may correspond to one semiconductor package footprint Fp. Each semiconductor package may include at least one semiconductor chip that is formed after performing a molding process. Accordingly, one semiconductor package to be formed later may have a first width Wp in a vertical direction (y direction). The semiconductor package may have a size that is nearly the same as that of the semiconductor chip, and thus, the semiconductor package may be a chip-scaled semiconductor package.

In the PCB 100 for MUF, the active area Aarea may be disposed in a vertical direction(y direction) at one side in the molding area Marea. In other words, the active area Aarea, as shown in FIG. 1, may be disposed in a vertical direction at one side on an upper side of the molding area Marea. Accordingly, a first interval Ym1 between an upper boundary line of the active area Aarea and an upper boundary line Mus of the molding area Marea may be smaller than a second interval Ym2 between a lower boundary line of the active area Aarea and a lower boundary line M1s of the molding area Marea. An upper edge Us portion of the PCB 100 for MUF may correspond to a gate portion into which a sealing material is injected during a molding process to be performed later, and a lower edge Ls portion of the PCB 100 for MUF may correspond to a vent portion from which air is discharged during the molding process.

For reference, an MUF process refers to a process for sealing an outer portion of the semiconductor chip and a space between the semiconductor chip and the PCB with a sealing resin through a one-shot molding process. The PCB used in the MUF process refers to a PCB for MUF. The PCB for MUF includes wiring lines that may be electrically connected to a plurality of bumps formed under the semiconductor chips. Also, in the PCB for MUF, a solder ball area may be provided to a surface opposite to a surface on which the semiconductor chips are mounted. A solder ball is formed in the solder ball area, and the semiconductor package may be connected to an external apparatus through the solder ball.

In general, the PCB for MUF may be manufactured by forming a body of the PCB for MUF of an epoxy resin including glass fibers, or a BT resin to be thin and then stacking thin copper foils on opposite sides of the body of the PCB for MUF to form wiring line patterns which are transmission paths of electrical signals. The wiring line patterns formed in upper and lower surfaces are electrically connected to one another via contact holes passing through the body of the PCB for MUF, and a photo solder resist (PSR) layer may be completely formed on the body of the PCB for MUF except for the wiring line patterns. The PCB for MUF according to the current embodiment is not limited to the above-described structure and material.

In the PCB 100 for MUF according to the current embodiment, the active area Aarea may be disposed farther from the lower boundary line M1s than the upper boundary line Mus of the molding area Marea, thereby preventing a void from being generated and increasing pressure to inject a sealing material during a molding process.

In detail, in the molding process, that is, in an MUF process, the PCB for MUF on which the semiconductor chips are mounted is disposed in a mold for molding (not shown), and a sealing resin is injected into the mold for molding at a predetermined pressure through a gate (not shown) of the mold. The sealing resin seals the semiconductor chips while moving in a vertical direction (y direction) from the gate portion to the vent portion. Since a sufficient space is formed between the semiconductor chips and on the semiconductor chips, the sealing resin may easily move in the space. Since a plurality of bumps are formed between the semiconductor chip and the PCB for MUF, a space where the sealing resin moves is very small, and thus, the sealing resin does not easily move in the space.

Consequently, the sealing resin is filled in the space between the semiconductor chip and the PCB for MUF later than a space between the semiconductor chips or a space over the semiconductor chips. Since the sealing material reaches a lower end portion of the mold for molding before the space between the semiconductor chip and the PCB for MUF is filled, at rows of the semiconductor chips that are farthest from the gate portion, that is, the semiconductor chips adjacent to the vent portion, the sealing material may no longer move, and a portion that is not filled with the sealing material, that is, a void, may be generated in the space between the semiconductor chips adjacent to the vent portion and the PCB for MUF.

However, in the PCB 100 for MUF according to the current embodiment, the active area Aarea is disposed far from the lower boundary line M1s of the molding area Marea, and thus, the semiconductor chips adjacent to the vent portion are disposed far from the lower end portion of the mold. In this regard, the lower boundary line M1s of the molding area Marea may be the lower end portion of the mold.

Consequently, when the sealing material reaches the lower end portion of the mold for molding through the space between the semiconductor chips or the space over the semiconductor chips, the space between the semiconductor chips adjacent to the vent portion and the PCB 100 for MUF may be sufficiently filled with the sealing material. Accordingly, a void may be prevented from being generated in the space between the semiconductor chips adjacent to the vent portion and the PCB 100 for MUF.

The second interval Ym2 may be smaller than the first width Wp in a vertical direction (y direction) of one semiconductor package to be formed later. If the second interval Ym2 is larger than the first width Wp, forming of the semiconductor package in the second interval Ym2 may be advantageous in terms of increasing the number of semiconductor packages in each PCB 100 for MUF.

The molding area Marea, as shown in FIG. 1, may be designed as one body. Conventionally, the molding area Marea is divided into a plurality of molding blocks on one PCB for MUF, and thus, there is a block distinguishing area for distinguishing the molding blocks. Since semiconductor chips are not disposed and a sealing material is not formed in the block distinguishing area, the block distinguishing area is a kind of wasted area in the PCB for MUF. However, in the PCB 100 for MUF according to the current embodiment, the molding area Marea is designed as one body, and a block distinguishing area does not exist. Accordingly, when semiconductor packages with a conventional PCB for MUF and the PCB 100 for MUF according to the current embodiment that have the same size are manufactured, the number of semiconductor packages with the PCB 100 for MUF according to the current embodiment may be increased equal to or more than about 30% compared to the conventional PCB for MUF including a block distinguishing area.

The peripheral area Parea refers to an outer portion of the molding area Marea. Guide holes GH may be formed in four vertices of the peripheral area Parea, respectively. Also, a plurality of guide holes GH′ may be formed in the peripheral area Parea (Mw) adjacent to the vent portion. For example, the guide holes GH′ of the peripheral area Parea adjacent to the vent portion may be formed to correspond to the respective semiconductor chips in a horizontal direction. The guide holes GH and GH′ may be used as identification marks during a molding process and may also be used as aligning means when moving the PCB 100 for MUF.

The molding area Marea may be symmetrically disposed with respect to the peripheral area Parea in a vertical direction (y direction). That is, an interval Yp1 between the upper end Us portion of the peripheral area Parea and the upper boundary line Mus of the molding area Marea may be the same as an interval Yp2 between the lower end Ls portion of the peripheral area Parea and the lower boundary line M1s of the molding area Marea. However, the inventive concepts are not limited thereto. For example, the molding area Marea may be asymmetrically disposed with respect to the peripheral area Parea in a vertical direction (y direction).

Hereinafter, for convenience of description, a repeated description of the elements described with respect to FIG. 1 will be omitted in describing other embodiments.

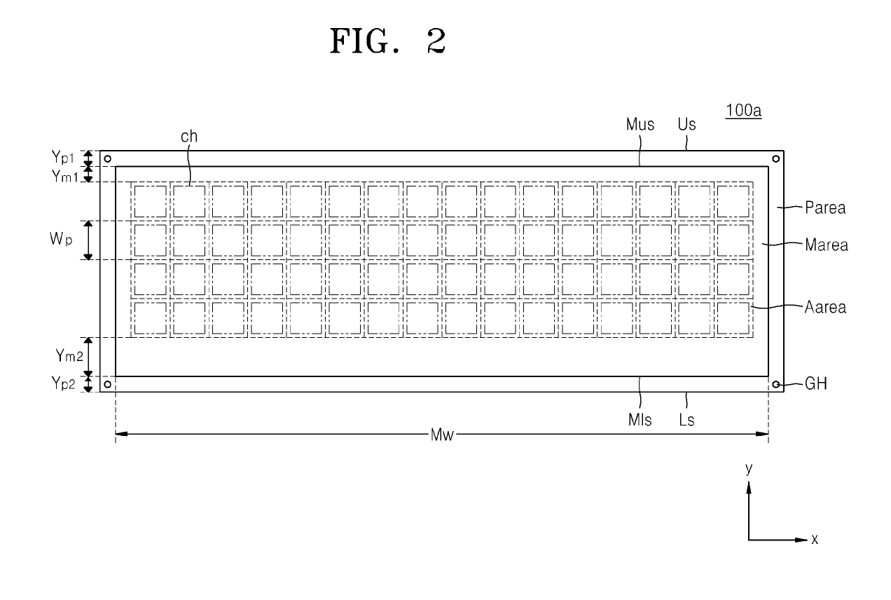

Referring to FIG. 2, the PCB 100a for MUF of the current embodiment is different from the PCB 100 for MUF of FIG. 1 in that in the PCB 100a for MUF of the current embodiment, guide holes GH′ are not formed in a peripheral area Parea adjacent to a vent portion. That is, as shown in FIG. 2, the guide holes GH may be formed in four vertices of the peripheral area Parea, respectively.

As shown in FIG. 1, the guide holes GH′ may be disposed in the peripheral area Parea adjacent to a vent portion. However, when the guide holes GH′ are formed in the peripheral area Parea adjacent to the vent portion, a sealing resin may leak through the guide holes GH′ during a molding process due to the guide holes GH′ disposed in the peripheral area Parea adjacent to the vent portion. In other words, if the guide holes GH′ are formed, curves are formed around the guide holes GH′ (thickness of peripheral area may not be uniform due to the curves), and thus, the guide holes GH′ may not tightly couple to the mold, thereby forming gaps between the guide holes GH′ and the mold. The sealing resin may leak through the gaps. Also, the molding process may be stopped due to the sealing resin leakage. In order to prevent the sealing resin from leaking through the gaps, the molding process may be performed by decreasing pressure to inject the sealing resin, thereby increasing the number of voids generated between the semiconductor chip and the PCB for MUF.

However, in the PCB 100a for MUF of the current embodiment, the guide hole GH′ is not formed in the peripheral area Parea adjacent to the vent portion, thereby preventing a sealing resin from leaking around the guide hole GH′. Accordingly, pressure to inject the sealing resin may be increased, and thus, a void may be prevented from being generated between a semiconductor chip and the PCB 100a for MUF. For reference, if the pressure to inject the sealing resin is increased, the sealing resin may be injected into a space between the semiconductor chip and the PCB 100a for MUF at a higher pressure, and thus, a possibility to generate a void may be decreased.

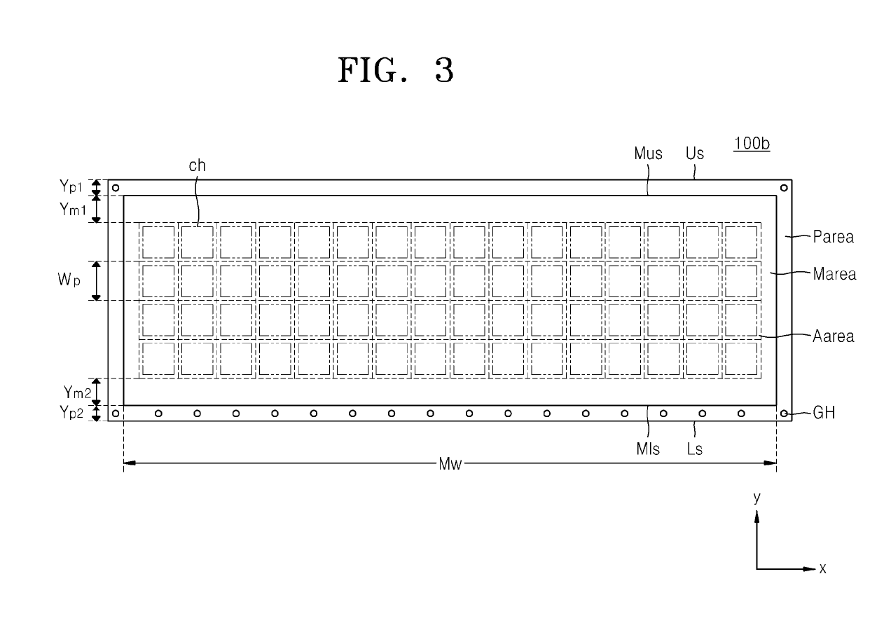

Referring to FIG. 3, the PCB 100b for MUF of the current embodiment is different from the PCB 100 for MUF of FIG. 1 in that in the PCB 100b for MUF of the current embodiment, active areas Aarea are symmetrically disposed in a vertical direction in a molding area Marea. That is, a first interval Ym1 may be the same as a second interval Ym2.

In the PCB 100b for MUF of the current embodiment, to design the molding area Marea as one body may be advantageous in terms of increasing the number of semiconductor packages in each PCB 100b for MUF.

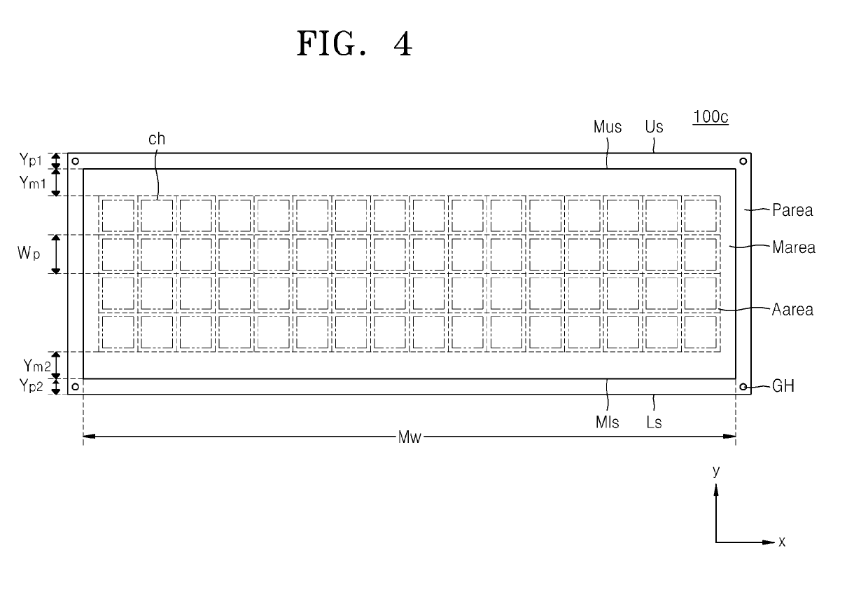

Referring to FIG. 4, the PCB 100c for MUF of the current embodiment is different from the PCB 100b for MUF of FIG. 3 in that in the PCB 100c for MUF of the current embodiment, a guide hole is not formed in a peripheral area Parea (Mw) adjacent to a vent portion. Accordingly, a sealing resin may be prevented from leaking from the guide hole. Also, by preventing the sealing resin from leaking, pressure to inject a sealing resin may be increased, thereby decreasing a possibility to generate a void between a semiconductor chip and the PCB 100c for MUF.

In the PCB 100c for MUF of the current embodiment, to design a molding area Marea as one body may be advantageous in terms of increasing the number of semiconductor packages in each PCB 100c for MUF.

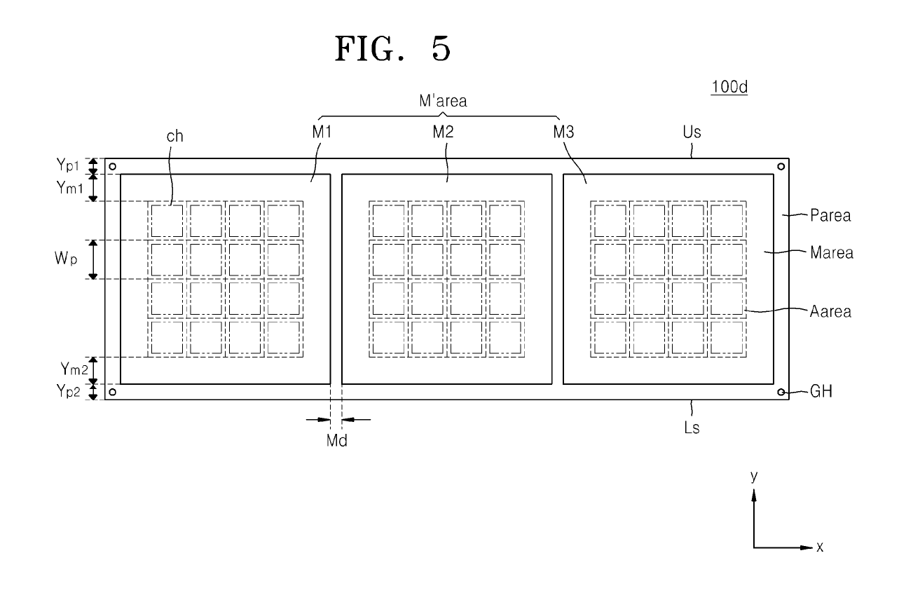

Referring to FIG. 5, a molding area Marea of the PCB 100d for MUF of the current embodiment may have a different structure from those of the PCBs 100 to 100c for MUF of FIGS. 1 to 4. That is, in the PCB 100d for MUF of the current embodiment, the molding area Marea may be divided into three molding blocks M1 to M3. The molding blocks M1 to M3 may be distinguished by a block distinguishing area Md.

When a molding process is performed later, a sealing material may be formed only in the molding blocks M1 to M3 and not in a block distinguishing area Md. In addition, a mold for molding may be formed into a shape corresponding to the molding blocks M1 to M3 and may contact the block distinguishing area Md in the PCB 100d for MUF.

In the PCB 100d for MUF of the current embodiment, a guide hole GH may be formed only in four vertices of a peripheral area Parea of the PCB 100d for MUF. Also, active areas Aarea may be symmetrically formed in a vertical direction in each of the molding blocks MI to M3. That is, a first interval Ym1 may be the same as a second interval Ym2 in each of the molding blocks M1 to M3.

In the PCB 100d for MUF of the current embodiment, since the guide hole GH′ is not formed in the peripheral area Parea (Mw) adjacent to a vent portion, a problem of leakage of a sealing resin may be resolved, thereby increasing pressure to inject the sealing resin. Thus, the generation of a void between a semiconductor chip and the PCB 100d for MUF may be decreased.

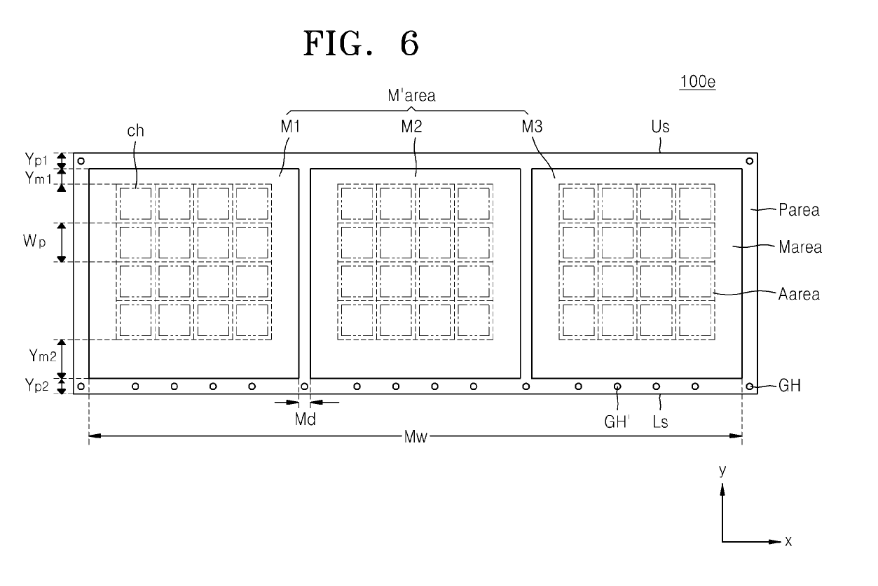

Referring to FIG. 6, the PCB 100e for MUF of the current embodiment is different from the PCB 100d for MUF of FIG. 5 in that in the PCB 100e for MUF of the current embodiment, active areas Aarea are asymmetrically disposed in a vertical direction in each of molding blocks M1, M2, and M3. In other words, a first interval Ym1 may be smaller than a second interval Ym2. Also, the second interval Ym2 may be smaller than a first width Wp in a vertical direction (y direction) of one semiconductor package to be formed later. To form the active areas Aarea asymmetrically has been described with reference to FIG. 1, and thus, a detailed description thereof will be omitted here.

In the PCB 100e for MUF of the current embodiment, a plurality of guide holes GH′ may be formed in a peripheral area Parea (Mw) adjacent to a vent portion, as shown in FIG. 1.

Referring to FIG. 7, the PCB 100f for MUF of the current embodiment is different from the PCB 100e for MUF of FIG. 6 in that in the PCB 100f for MUF, a plurality of guide holes GH are respectively formed only in four vertices of the peripheral area Parea of the PCB 100f for MUF. In other words, a plurality of guide holes GH′ may not be formed in the peripheral area Parea (Mw) adjacent to a vent portion. Accordingly, as described above with reference to FIG. 2, problems of leakage of a sealing material and generation of a void may be resolved.

So far, the PCBs 100 to 100f for MUF of FIGS. 1 to 7 have been described as having various structures. However, the inventive concepts are not limited thereto. In other words, various other PCBs for MUF in which an active area is disposed in a vertical direction at one side in a molding area and/or a guide hole is not formed in a peripheral area Parea (Mw) adjacent to a vent portion may be used.

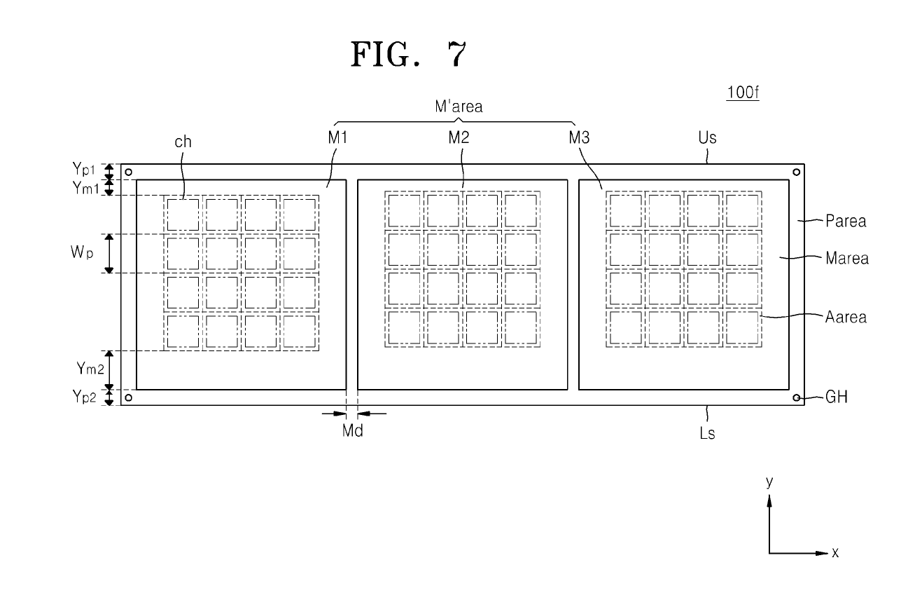

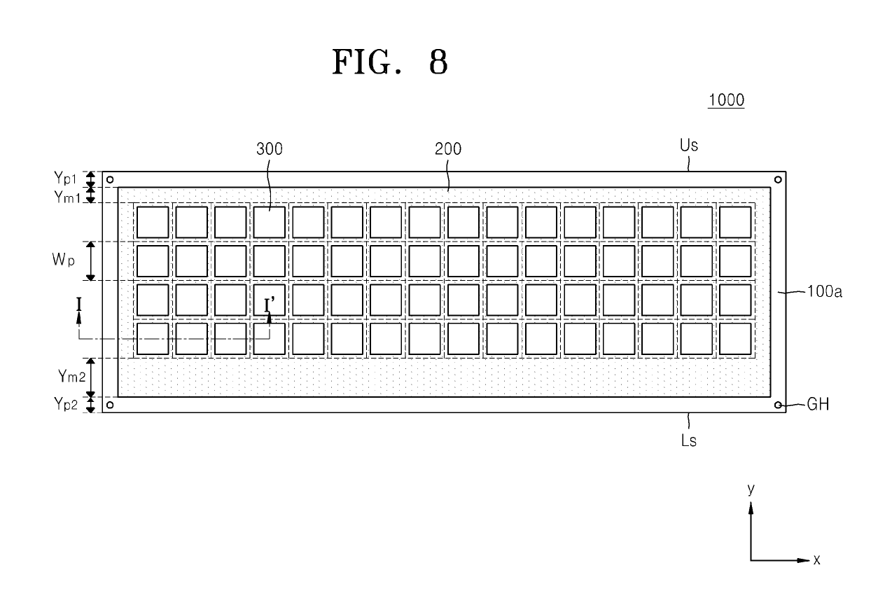

FIG. 8 is a plan view of a PCB molding structure 1000 using the PCB 100a for MUF of FIG. 2, according to an embodiment of the inventive concept.

Referring to FIG. 8, the PCB molding structure 1000 may include the PCB 100a for MUF, a sealing material 200, and a plurality of semiconductor chips 300.

The PCB 100a for MUF may be the same as the PCB 100a for MUF described with reference to FIG. 2. Accordingly, in the PCB 100a for MUF, active areas may be disposed asymmetrically in a vertical direction in a molding area. Also, a plurality of guide holes GH may be formed only in four vertices of the PCB 100a for MUF.

The semiconductor chips 300 may be mounted on the chip mounting portions ch (see FIG. 2) in the active area of the PCB 100a for MUF, respectively. The semiconductor chips 300 may be mounted on the PCB 100a for MUF by using a flip chip bonding method. In other words, the semiconductor chips 300 may be mounted on the chip mounting portions ch of the PCB 100a for MUF, respectively, through a plurality of bumps (not shown) formed under the semiconductor chips 300 in an array. As shown in FIG. 2, the active area is disposed asymmetrically in a vertical direction in the molding area, and thus, an array of the semiconductor chips 300 mounted in the active area may be disposed asymmetrically in a vertical direction with respect to the sealing material 200.

Two or more semiconductor chips 300 instead of one semiconductor chip 300 may be stacked in each chip mounting portion ch, which will be described in detail with reference to FIG. 14.

The sealing material 200 is formed on a sealing area to seal the plurality of semiconductor chips 300. The sealing material 200 may be formed of an epoxy molding compound (EMC) resin. As described above, the sealing material 200 seals not only an outer portion of the semiconductor chips 300 but also a space between the semiconductor chips 300 and the PCB 100a for MUF through an MUF process.

Top surfaces of the semiconductor chips 300 may be exposed by the sealing material 200. Since the top surfaces of the semiconductor chips 300 are exposed by the sealing material 200, the MUF process may be referred to as an exposed-MUF (eMUF) process. The eMUF process may be performed by controlling an internal height of a mold for molding to be the same as a height of the top surface of the semiconductor chip 300 in order to prevent the sealing material 200 from being formed on the top surfaces of the semiconductor chips 300 during a MUF process.

In the PCB molding structure 1000 of the current embodiment, the array of the semiconductor chips 300 are disposed asymmetrically in a vertical direction with respect to the sealing material 200, and the guide holes GH are formed only in four vertices of the PCB 100a for MUF, thereby manufacturing a semiconductor package not having a void. Also, the MUF process may be stably performed by resolving a problem of leakage of a sealing resin. Furthermore, since the sealing material 200 is formed as one body, the number of semiconductor packages in each PCB for MUF may be increased. For reference, dashed portions of the PCB molding structure 1000 may be sawn to divide into individual semiconductor packages, thereby completing manufacture of a semiconductor package.

In the current embodiment, the PCB molding structure 1000 using the PCB 100a for MUF of FIG. 2 has been described, but the inventive concepts are not limited thereto. That is, the PCB molding structure 1000 may be embodied by using any of the PCBs 100, and 100b to 100f for MUF of FIGS. 1, and 3 to 7. Also, various other PCBs for MUF in which an active area is disposed in a vertical direction at one side in a molding area and/or a guide hole is not formed in a peripheral area Parea (Mw) adjacent to a vent portion may be used.

Hereinafter, for convenience of description, a repeated description of the elements described with respect to FIG. 8 will be omitted.

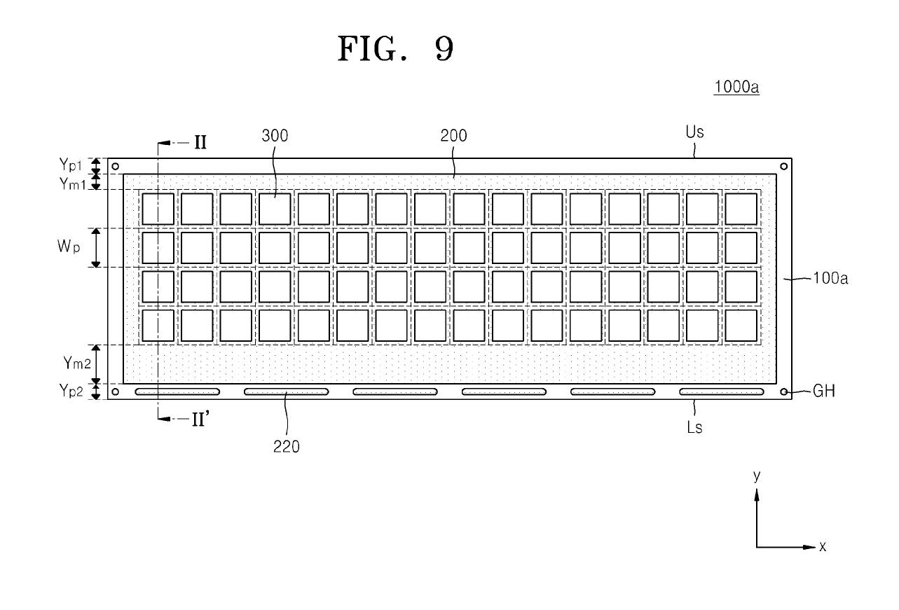

FIG. 9 is a plan view of a PCB molding structure 1000a using the PCB 100a for MUF of FIG. 2, according to another embodiment of the inventive concepts.

Referring to FIG. 9, the PCB molding structure 1000a of the current embodiment may be similar to the PCB molding structure 1000 of FIG. 8. However, in the PCB molding structure 1000a of the current embodiment, a plurality of reservoir patterns 220 having a line shape may be formed in a peripheral area Parea (Mw) adjacent to a vent portion of the PCB 100a for MUF. A reservoir (not shown) may be formed in a mold for molding in order for a sealing resin to smoothly move during an MUF process. If the sealing resin reaches an end of the mold for molding, the sealing resin moves to the reservoir, thereby forming the reservoir patterns 220.

For reference, the reservoir is formed in the mold for molding due to the fact that when a second interval Ym2 is relatively small as in the PCB 100b for MUF of FIG. 3, a space where the sealing resin may move even after the sealing resin reaches the mold for molding may be formed to allow the sealing resin to move more downwards. Thus, a space between a semiconductor chip adjacent to a vent portion and the PCB 100b for MUF may be filled with the sealing resin, thereby preventing a void from being generated between the space between the semiconductor chip adjacent to the vent portion and the PCB 100b for MUF. Also, even when a guide hole is formed in the peripheral area Parea (Mw) adjacent to the vent portion of the PCB 100 for MUF, a reservoir may be formed in a mold for molding to prevent the sealing resin from leaking through the guide hole.

FIG. 10 is a plan view of a PCB molding structure 1000b using the PCB 100a for MUF of FIG. 2, according to another embodiment of the inventive concepts.

Referring to FIG. 10, the PCB molding structure 1000b of the current embodiment may be similar to the PCB molding structure 1000 of FIG. 8. However, top surfaces of a plurality of semiconductor chips 300 may not be exposed through a top surface of a sealing material 200a. In FIG. 10, the semiconductor chips 300 are shown as dashed lines in order to show that the top surfaces of the semiconductor chips 300 are not exposed.

The PCB molding structure 1000b of the current embodiment may be formed through a general MUF process instead of an eMUF process. In other words, a space between the top surfaces of the semiconductor chips 300 and a ceiling portion inside the mold for molding may be maintained by making an internal height of a mold for molding high, and a sealing resin may be filled in the space, and thus the top surfaces of the semiconductor chips 300 may not be exposed through the sealing material 200a, as shown in FIG. 10.

As described above, the PCB molding structure 1000b may be sawed at proper intervals after performing a molding process, thereby completing manufacture of an individual semiconductor package. The manufactured semiconductor package may be a good quality semiconductor package not having a void based on the PCB 100a for MUF of the current embodiment and a PCB molding structure using the PCB 100a for MUF.

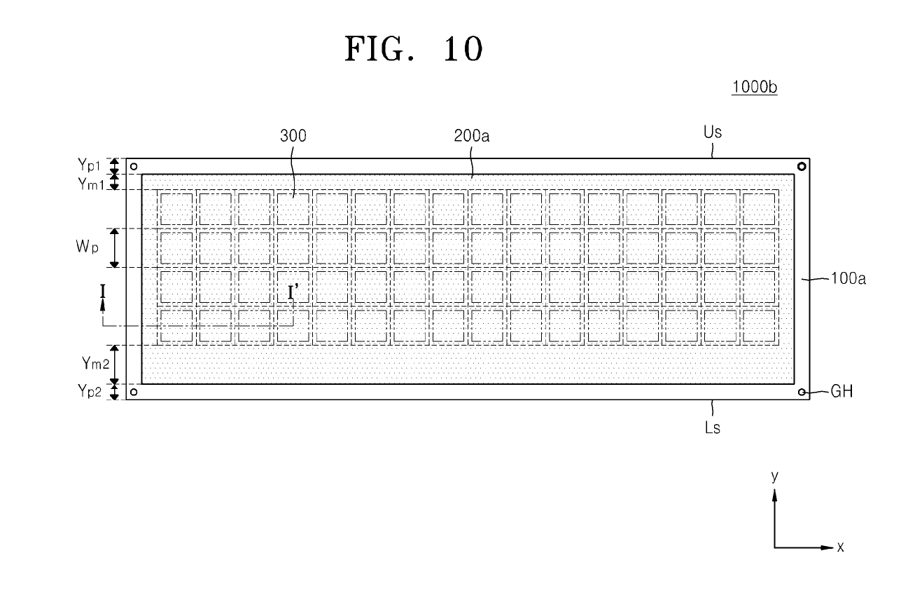

FIG. 11 is a cross-sectional view of the PCB molding structure 1000 using the PCBa 100 for MUF of FIG. 8 taken along a line I-P.

Referring to FIG. 11, the PCB molding structure 1000 of the current embodiment may include the PCB 100a for MUF, the sealing material 200, and the semiconductor chips 300. The semiconductor chips 300 may be mounted on the PCB 100a for MUF through a plurality of bumps 320. Also, top surfaces of the semiconductor chips 300 may not be covered by the sealing material 200 and may be exposed to the outside.

As described above, the sealing material 200 may fill not only in side surfaces of the semiconductor chips 300 but also in spaces between the semiconductor chips 300 and the PCB 100a for MUF, that is, portions where the bumps 320 are formed, through an eMUF process.

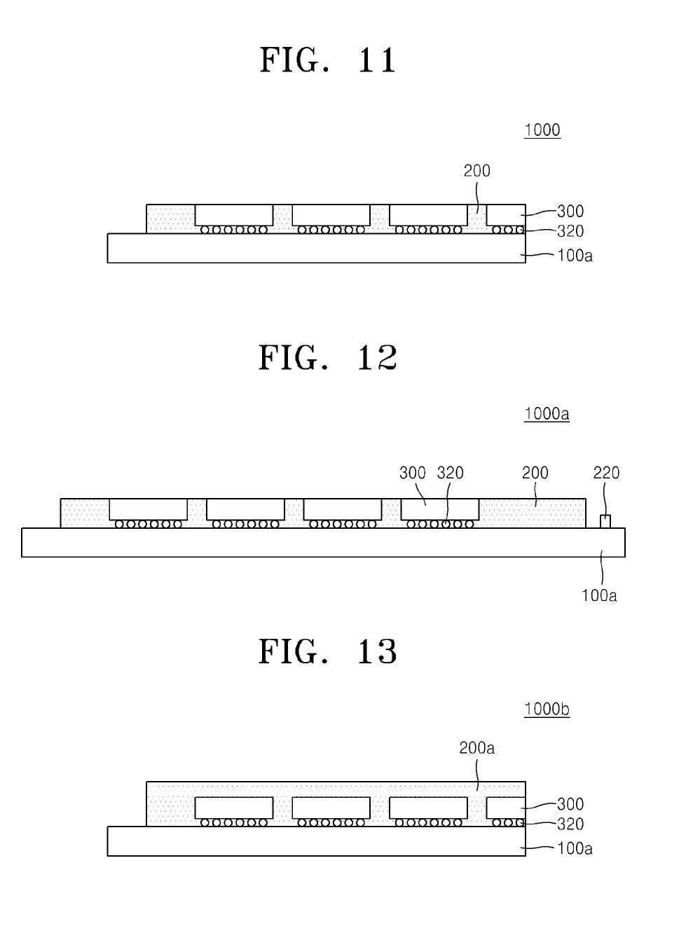

FIG. 12 is a cross-sectional view of the PCB molding structure 1000a using the PCB 100a for MUF of FIG. 9 taken along a line II-IP.

Referring to FIG. 12, the PCB molding structure 1000a of the current embodiment may be similar to the PCB molding structure 1000 of FIG. 11. However, as described above with reference to FIG. 9, the reservoir patterns 220 may be further formed in the peripheral area adjacent to a vent portion of the PCB 100a for MUF. The reservoir patterns 220 may be formed in a line shape and may be formed of the same material as that of the sealing material 200.

As shown in FIG. 12, since the semiconductor chips 300 are disposed at the left side in the PCB molding structure 1000a, the sealing material 200 may be formed long at right side of the semiconductor chips 300 of the PCB molding structure 1000a, which may correspond to a feature that the first interval Ym1 is smaller than the second interval Ym2 in FIG. 9.

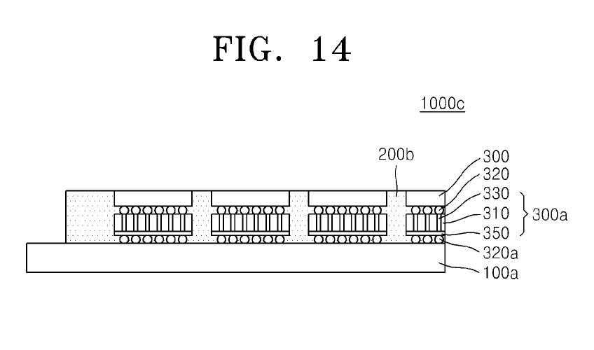

FIG. 13 is a cross-sectional view of the PCB molding structure 1000b of the PCB 100a for MUF of FIG. 10 taken along a line I-I′.

Referring to FIG. 13, the PCB molding structure 1000b of the current embodiment may be formed in such a way that the sealing material 200a completely covers the top surfaces of the semiconductor chips 300, as described above with reference to FIG. 10. The PCB molding structure 1000b of the current embodiment is the same as the PCB molding structure 1000 of FIG. 11 in that the semiconductor chips 300 are mounted on the PCB 100a for MUF through the plurality of bumps 320 except the sealing material 200a covers the top surfaces of the semiconductor chips 300 in the current embodiment.

FIG. 14 is a cross-sectional view of a PCB molding structure 1000c of the PCB 100a for MUF of FIG. 8 taken along a line I-I′, according to another embodiment of the inventive concepts.

Referring to FIG. 14, the PCB molding structure 1000c of the current embodiment may include the PCB 100a for MUF, a sealing material 200b, and a plurality of semiconductor chips 300a and 300.

The PCB 100a for MUF and the sealing material 200b may be the same as the PCB 100a for MUF and the sealing material 200 of the PCB molding structure 1000 of FIG. 11, respectively. However, unlike the PCB molding structure 1000 of FIG. 11, in the PCB molding structure 1000c of the current embodiment, two semiconductor chips 300a and 300 may be mounted on each chip mounting portion ch (see FIG. 2) of the PCB 100a for MUF. In other words, the semiconductor chip 300a and the semiconductor chip 300 may be mounted on each chip mounting portion ch of the PCBa 100 for MUF.

Each semiconductor chip 300a may include a body 310, a plurality of through silicon vias (TSVs) 330, and a protection layer 350. The body 310 may include a base substrate (not shown), an integrated circuit layer (not shown), an intermetallic insulating layer (not shown), and the like. The TSVs 330 may be formed to penetrate the body 310 and may be formed of a conductive material, for example, a metal. The TSVs 330 may be electrically connected to a plurality of bumps 320a formed under the semiconductor chip 300a and a plurality of bumps 320 formed above the semiconductor chip 300a.

In the PCB molding structure 1000c of the current embodiment, although the semiconductor chip 300a has a simple structure, the structure of the semiconductor chip 300a is not limited thereto. In other words, various other semiconductor chip structures on PCB molding structures in which an active area is disposed in a vertical direction at one side in a molding area and/or a guide hole is not formed in a peripheral area adjacent to a vent portion may be used.

The semiconductor chip 300 of the current embodiment may be the same as the semiconductor chip 300 of the PCB molding structure 1000 of FIG. 11 except that the semiconductor chip 300 is stacked on the semiconductor chip 300a instead of being directly stacked on the PCB 100a for MUF. Top surfaces of the semiconductor chip 300 may be exposed through a top surface of the sealing material 200b. Alternatively, the sealing material 200b may be formed to not expose the top surfaces of the semiconductor chip 300, similar to the PCB molding structure 1000b of FIG. 13. The semiconductor chips 300 may have a structure in which the TSVs 330 are formed, similar to the semiconductor chip 300a.

Although the PCB molding structure 1000c of the current embodiment has a structure in which two semiconductor chips 300a and 300 are stacked on each chip mounting portion ch, the inventive concepts are not limited thereto. In other words, three or more semiconductor chips may be stacked on each chip mounting portion ch of the PCB 100a for MUF. When three or more semiconductor chips are stacked on each chip mounting portion ch of the PCB 100a for MUF, TSVs may be formed in the semiconductor chips except for an uppermost semiconductor chip. Alternatively, the TSVs may also be formed in the uppermost semiconductor chip.

In a PCB for MUF and a PCB molding structure of the inventive concepts, semiconductor chips may be disposed towards a portion into which a sealing material is injected in a molding area, and thus, a one-shot molding process may be smoothly performed and a problem of generation of a void may be resolved.

Also, a guide ring is not formed around a vent portion on a PCB, and thus, a sealing material may be prevented from leaking, thereby smoothly performing a molding process.

Furthermore, by resolving a problem of leakage of a sealing material, the sealing material may be injected at higher pressure, and thus, a problem of generation of a void may be resolved.

While example embodiments have been particularly shown and described, it will be understood by one of ordinary skill in the art that variations in form and detail may be made therein without departing from the spirit and scope of the inventive concepts defined by the following claims.

What is claimed is:

1. A printed circuit board (PCB) for molded underfill (MUF), the PCB comprising:
a molding area on which a plurality of semiconductor chips are mounted, the molding area being sealed;
a peripheral area around a periphery of the molding area, the peripheral area configured to contact a mold during a molding process, the peripheral area including,
a first side adjacent to an injection portion of the molding area into which a molding material is injected, and
a second side parallel to the first side, the second side being adjacent to a vent portion of the molding area, the vent portion of the molding area configured to discharge air during the molding process; and
an active area, the active area being within the molding area, the semiconductor chips being in the active area, the active area being located closer to the first side than the second side of the peripheral area.

2. The PCB of claim 1, wherein
the active area includes a plurality of semiconductor package footprints, each semiconductor package footprint including one of the semiconductor chips, and
a distance between an edge of the active area and an edge of the molding area nearest the second side is equal to or less than a width of one semiconductor packagefootprint.

3. The PCB of claim 1, wherein the PCB for MUF has a rectangular strip structure, and guide holes are located only in four vertices of the PCB for MUF.

4. The PCB of claim 1, wherein no guide hole is located in a center portion of the second side of the peripheral area, and a thickness of the PCB for MUF of the second side is uniform.

5. The PCB of claim 1, wherein the molding area is one body and a block distinguishing area is not formed in the PCB for MUF.

6. A printed circuit board (PCB) for molded underfill (MUF), the PCB comprising:
a molding area on which a plurality of semiconductor chips are mounted, the molded area being sealed; and
a peripheral area around the molding area, the peripheral area contacting a mold during a molding process, the peripheral area including a first side adjacent to an injection portion of the molding area into which a molding material is injected during a molding process and a second side that faces the first side, the second side being adjacent to a portion of the molding area from which air is discharged,
a thickness of the second side being uniform.

7. The PCB of claim 6, wherein the PCB for MUF has a rectangular strip structure, guide holes are located only in four vertices of the PCB for MUF, and no guide hole is in a center portion of the second side.

8. The printed circuit board (PCB) of claim 6, wherein
the semiconductor chips are mounted on an active area of the PCB for MUF; and
a sealing material is located on the molding area and the sealing material seals the semiconductor chips.

9. The PCB of claim 8, wherein
the active area includes a plurality of semiconductor package footprints, each semiconductor package footprint including one of the semiconductor chips, and
a distance between an edge of the active area and an edge of the molding area nearest the second side is equal to or less than a width of one semiconductor package footprint.

10. The PCB of claim 8, wherein the PCB for MUF has a rectangular strip structure, guide holes only in four vertices of the PCB for MUF, no guide hole in a center portion of the second side, and a thickness of the PCB for MUF of the second side being uniform.

11. The PCB of claim 8, wherein the sealing material is formed as one body.

12. The PCB of claim 8, wherein top surfaces of the semiconductor chips are exposed through the sealing material.

13. The PCB of claim 8, wherein each of the semiconductor chips is mounted on the PCB for MUF through a plurality of bumps, and the sealing material is filled in a space between the semiconductor chips and the PCB for MUF.

14. The PCB of claim 8, wherein a reservoir pattern is on the second side of the peripheral area.

15. The PCB of claim 8, wherein two or more semiconductor chips are stacked on the active area.

16. A printed circuit board (PCB) for molded underfill (MUF), the PCB comprising:
an injection side configured to accept sealing material during a molding process,
a vent side configured to discharge air during the molding process, and
an active area, the active area configured to receive semiconductor chips thereon, the active area being located closer to the injection side than to the vent side of the PCB and the active area configured to be sealed during the molding process.

17. The PCB of claim 16, further comprising:
semiconductor chips on the active area.

18. The PCB of claim 17 wherein top surfaces of the semiconductor chips are covered with sealing material during a molding process.

19. The PCB of claim 17, further comprising:
a plurality of stacked semiconductor chips.

20. The PCB of claim 16, further comprising:
a reservoir portion adjacent to the vent portion of the PCB.
